(19) United States
(12) Patent Application Publication
(10) Pub. No.: US 2023/0240111 A1
(43) Pub. Date: Jul. 27, 2023

(54) PIXEL ARRANGEMENT STRUCTURE, DISPLAY PANEL AND MASK ASSEMBLY

(71) Applicant: Hefei Visionox Technology Co., Ltd., Hefei (CN)

(72) Inventors: Lan LAN, Hefei (CN); Shaoya QIU, Hefei (CN); Qingqing DONG, Hefei (CN); Dandan FENG, Hefei (CN); Yi QU, Hefei (CN); Menghua KANG, Hefei (CN)

(73) Assignee: Hefei Visionox Technology Co., Ltd., Hefei (CN)

(21) Appl. No.: 18/190,254

(22) Filed: Mar. 27, 2023

Related U.S. Application Data
(63) Continuation of application No. PCT/CN2021/120882, filed on Sep. 27, 2021.

(30) Foreign Application Priority Data
Dec. 10, 2020 (CN) 202011435312.7

(51) Int. Cl. H10K 59/35; H10K 71/16

(52) U.S. Cl. CPC H10K 59/353; H10K 59/352; H10K 71/166

(57) ABSTRACT

A pixel arrangement structure, a display panel and a mask assembly. The pixel arrangement structure includes a plurality of repeat units arranged in an array, each of the repeat units is an N polygon, N≥4 and N is an even number, the repeat unit includes: a first pixel group including at least two first sub-pixels; at least two second pixel groups, each of the second pixel groups includes two second sub-pixels; and at least two third pixel groups, each of the third pixel groups includes two third sub-pixels, the at least two second pixel groups and the at least two third pixel groups are alternately arranged on a peripheral side of the first pixel group.

### CROSS REFERENCE TO RELATED APPLICATION

The present application is a continuation of International Application No. PCT/CN2021/120882 filed on Sep. 27, 2021, which claims the priority to Chinese Patent Application No. 202011435312.7 filed on Dec. 10, 2020, both of which are incorporated herein by reference in their entireties.

### TECHNICAL FIELD

The present application relates to the field of display technology, and particularly, to a pixel arrangement structure, a display panel and a mask assembly.

### BACKGROUND

Organic Light-Emitting Diode (OLED) is an active light-emitting device. Compared with the traditional Liquid Crystal Display (LCD) display, OLED display does not require backlight and is self-luminous. OLED utilizes a thin film of organic material and a glass substrate, and when an electric current flows through, the organic material will emit light. Therefore, OLED display panels can save significant power, be made light and thin, withstand a wider range of temperature change than LCD display panels and have large viewing angles. OLED display panels are expected to become the next generation of flat panel display technology after LCD and are currently one of the most popular technologies in the field of flat panel display technology.

### SUMMARY

The embodiments of the present application provide a pixel arrangement structure, a display panel and a mask assembly, aiming to improve the display effect of the pixel arrangement structure.

Embodiments of a first aspect of the present application provide a pixel arrangement structure including a plurality of repeat units arranged in an array, each of the repeat units being an N polygon, N≥4 and N being an even number, in which the repeat unit includes: a first pixel group including at least two first sub-pixels; at least two second pixel groups, each of the second pixel groups including two second sub-pixels; and at least two third pixel groups, each of the third pixel groups including two third sub-pixels, the at least two second pixel groups and the at least two third pixel groups being alternately arranged on a peripheral side of the first pixel group.

Embodiments of a second aspect of the present application further provide a display panel including the pixel arrangement structure as described above.

Embodiments of a third aspect of the present application further provide a mask assembly to be applied for evaporation of the pixel arrangement structure as described above, the mask assembly including: a first mask plate configured for evaporation of the first sub-pixels and including a first evaporation opening adapted to an outer contour of a plurality of the first sub-pixels that are adjacent in the pixel arrangement structure; a second mask plate configured for evaporation of the second sub-pixels and including a second evaporation opening adapted to an outer contour of a plurality of the second sub-pixels that are adjacent in the pixel arrangement structure; and a third mask plate configured for evaporation of the third sub-pixels and including a third vaporization opening adapted to an outer contour of a plurality of the third sub-pixels that are adjacent in the pixel arrangement structure.

According to the pixel arrangement structure of the embodiments of the present application, the pixel arrangement structure includes a plurality of repeat units arranged in an array. The repeat unit is an N polygon, N≥4 and N is an even number, so that the edges of adjacent two repeat units can be oppositely arranged, the space between the adjacent two repeat units is reduced, the density of pixel arrangement is increased, and thus the display effect is improved. The repeat unit includes the first pixel group, the second pixel group and the third pixel group, the second pixel group includes two second sub-pixels, the third pixel group includes two third sub-pixels, and the second pixel group and the third pixel group are alternately arranged on a peripheral side of the first pixel group, so that the second sub-pixels in the second pixel group are adjacent to the third sub-pixels in the third pixel group and the first sub-pixels, and the second pixel group and the third pixel group share one first sub-pixel, the pixel density of the pixel arrangement structure can be increased, and the display effect is improved.

### BRIEF DESCRIPTION OF THE DRAWINGS

Other features, objects and advantages of the present application will become more apparent from reading the following detailed description of the non-limiting embodiments with reference to the accompanying drawings, in which the same or similar reference numerals represent the same or similar features.

FIG. 1 shows a schematic structural diagram of a repeat unit in a pixel arrangement structure according to an embodiment of the first aspect of the present application;

FIG. 2 shows a schematic structural diagram of a repeat unit in a pixel arrangement structure according to another embodiment of the first aspect of the present application;

FIG. 3 shows a schematic structural diagram of a repeat unit in a pixel arrangement structure according to yet another embodiment of the first aspect of the present application;

FIG. 4 shows a schematic structural diagram of a repeat unit in a pixel arrangement structure according to yet another embodiment of the first aspect of the present application;

FIG. 5 shows a schematic structural diagram of a repeat unit in a pixel arrangement structure according to yet another embodiment of the first aspect of the present application;

FIG. 6 shows a schematic structural diagram of a pixel arrangement structure according to an embodiment of the first aspect of the present application;

FIG. 7 shows a schematic structural diagram of a repeat unit in a pixel arrangement structure according to yet another embodiment of the first aspect of the present application;

FIG. 8 shows a schematic structural diagram of a repeat unit in a pixel arrangement structure according to yet another embodiment of the first aspect of the present application;

FIG. 9 shows a schematic structural diagram of a pixel arrangement structure according to another embodiment of the first aspect of the present application;

FIG. 10 shows a schematic structural diagram of a repeat unit in a pixel arrangement structure according to yet another embodiment of the first aspect of the present application;

FIG. 11 shows a schematic structural diagram of a repeat unit in a pixel arrangement structure according to yet another embodiment of the first aspect of the present application;

FIG. 12 shows a schematic structural diagram of a pixel arrangement structure according to yet another embodiment of the first aspect of the present application;

FIG. 13 shows a schematic structural diagram of a pixel arrangement structure according to yet another embodiment of the first aspect of the present application;

FIG. 14 shows a schematic structural diagram of a repeat unit in a pixel arrangement structure according to yet another embodiment of the first aspect of the present application;

FIG. 15 shows a schematic structural diagram of a repeat unit in a pixel arrangement structure according to yet another embodiment of the first aspect of the present application;

FIG. 16 shows a schematic structural diagram of a repeat unit in a pixel arrangement structure according to yet another embodiment of the first aspect of the present application;

FIG. 17 shows a schematic structural diagram of a repeat unit in a pixel arrangement structure according to yet another embodiment of the first aspect of the present application;

FIG. 18 shows a schematic structural diagram of a pixel arrangement structure according to yet another embodiment of the first aspect of the present application;

FIG. 19 shows a schematic structural diagram of a display panel according to an embodiment of the present application;

FIG. 20 shows a partially enlarged schematic structural diagram of area I in FIG. 19; and

FIG. 21 shows a cross-sectional view at A-A in FIG. 20 according to an embodiment of the present application.

### DETAILED DESCRIPTION

Features and exemplary embodiments of various aspects of the present application will be described in detail below. In the following detailed description, many specific details are presented to provide a comprehensive understanding of the present application. Nonetheless, it will be apparent to those skilled in the art that the present application can be implemented without some of these specific details. The following description of the embodiments is intended only to provide a better understanding of the present application by illustrating examples of the present application. In the accompanying drawings and the following description, at least some of the well-known structures and techniques are not illustrated to avoid unnecessary ambiguity in the present application; and moreover, the dimensions of some structures may be exaggerated for clarity. In addition, the features, structures, or characteristics described below may be combined in any suitable manner in one or more embodiments.

The orientation words used in the following description are the directions illustrated in the drawings and are not intended to limit the specific structure of the embodiments of the present application. In the description of the present application, it should be noted that, unless otherwise expressly specified and limited, the terms “mount” and “connect” should be understood in a broad sense, e.g., they may represent a fixedly connection, a detachably connection or an integrally connection; and alternatively, a direct connection or an indirect connection. For those ordinarily skilled in the art, the specific meaning of the above terms in the present application may be understood according to the context.

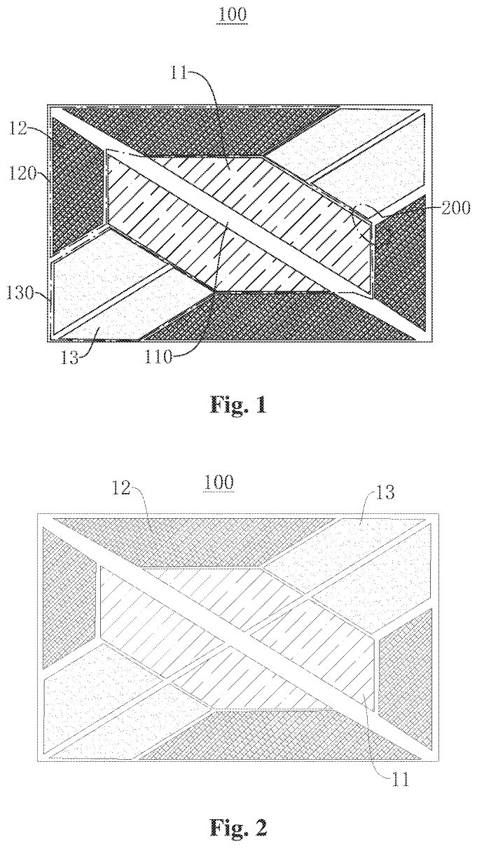

For a better understanding of the present application, the pixel arrangement structure, the display panel, the electronic device and the mask assembly according to the embodiments of the present application are described in detail below with reference to FIGS. 1 to 21.

Referring to FIG. 1, which shows a schematic structural diagram of a repeat unit 100 in a pixel arrangement structure according to the embodiments of the present application.

The pixel arrangement structure according to the embodiments of the present application includes a plurality of repeat units 100 arranged in an array, and as shown in FIG. 1, the repeat unit 100 is an N polygon, N≥4 and N is an even number, the repeat unit 100 includes: a first pixel group 110 including at least two first sub-pixels 11; a second pixel group 120 including two second sub-pixels 12; and a third pixel group 130 including two third sub-pixels 13, the at least two second pixel groups 120 and the at least two third pixel groups 130 are alternately arranged on a peripheral side of the first pixel group 110.

FIG. 1 defines the first pixel group 110, the second pixel group 120 and the third pixel group 130 with dot dash lines, which do not limit the structure of the pixel arrangement structure according to the embodiments of the present application.

According to the pixel arrangement structure of the embodiments of the present application, the pixel arrangement structure includes a plurality of repeat units 100 arranged in an array. The repeat unit 100 is an N polygon, N≥4 and N is an even number, so that the edges of adjacent two repeat units 100 can be oppositely arranged, the space between the adjacent two repeat units 100 is reduced, the density of pixel arrangement is increased, and thus the display effect is improved. The repeat unit 100 includes the first pixel group 110, the second pixel group 120 and the third pixel group 130, the second pixel group 120 includes two second sub-pixels 12, the third pixel group 130 includes two third sub-pixels 13, and the second pixel group 120 and the third pixel group 130 are alternately arranged on a peripheral side of the first pixel group, so that the second sub-pixels 12 in the second pixel group 120 are adjacent to the third sub-pixels 13 in the third pixel group 130 and the first sub-pixels 11, and the second pixel group 120 and the third pixel group 130 share one first sub-pixel 11, the pixel density of the pixel arrangement structure can be increased, and the display effect is improved.

In addition, in the present application, the second pixel group 120 and the third pixel group 130 share one first sub-pixel 11, which can increase the pixel density when the support capacity of a mask plate cannot be improved, the display effect can be further improved.

The first sub-pixel 11, the second sub-pixel 12 and the third sub-pixel 13 may be set in a variety of ways, for example, the first sub-pixel 11 is a blue sub-pixel, the second sub-pixel 12 is a red sub-pixel and the third sub-pixel 13 is a green sub-pixel. In other embodiments, the first sub-pixel 11 may be a red or a green sub-pixel, the second sub-pixel 12 may be a blue or green sub-pixel, and the third sub-pixel 13 may be a blue or red sub-pixel, as long as the first sub-pixel 11, the second sub-pixel 12 and the third sub-pixel 13 are of different colors from each other.

In the repeat unit 100, the numbers of the first sub-pixels 11, the second sub-pixels 12 and the third sub-pixels 13 may be set in a variety of ways. For example, in the repeat unit 100, a ratio of numbers of the first sub-pixels 11, the second sub-pixels 12 and the third sub-pixels 13 is 1:2:2, the first sub-pixel 11, the second sub-pixel 12 and the third sub-pixel 13 form a pixel display unit 200, and the first sub-pixel 11 is shared by adjacent two pixel display units 200. FIG. 1 illustrates the three sub-pixels included in one pixel display unit 200 with a dotted ellipse, which does not limit the structure of the pixel arrangement structure according to the embodiments of the present application.

In these optional embodiments, the number of the first sub-pixels 11 is small and the first sub-pixel 11 is shared by adjacent two pixel display units 200, the pixel density is maintained while the number of the first sub-pixels 11 is reduced, the aperture ratio of the pixels is increased and the area of the first sub-pixels 11 is increased, and moreover, the area of the opening on the mask plate corresponding to the first sub-pixels 11 is increased and the structure of the mask plate is simplified.

Optionally, when the ratio of numbers of the first sub-pixels 11, the second sub-pixels 12 and the third sub-pixels 13 is 1:2:2, the first sub-pixels 11 are blue sub-pixels. The light-emitting efficiency of a blue sub-pixel is usually lower than that of a green sub-pixel and a red sub-pixel, and the first sub-pixels 11 are blue sub-pixels, which can increase the area of the blue sub-pixels and improve the overall service life of the blue sub-pixels.

In some other embodiments, referring to FIG. 2, which shows a schematic structural diagram of a repeat unit 100 in a pixel arrangement structure according to another embodiment of the first aspect of the present application.

As shown in FIG. 2, in the repeat unit 100, the first pixel group 110 comprises two first sub-pixels 11, and a ratio of the numbers of the first sub-pixels 11, the second sub-pixels 12 and the third sub-pixels 13 is 1:1:1.

In these optional embodiments, the ratio of the numbers of the first sub-pixels 11, the second sub-pixels 12 and the third sub-pixels 13 is 1:1:1, and the first sub-pixels 11, the second sub-pixels 12 and the third sub-pixels 13 form a pixel display unit 200 with all true sub-pixels, which can improve the color rendering and display effect of the pixel arrangement structure.

When the ratio of the numbers of the first sub-pixels 11, the second sub-pixels 12 and the third sub-pixels 13 is 1:1:1, the first sub-pixel 11 may be any one of a blue sub-pixel, a red sub-pixel and a green sub-pixel.

In the pixel arrangement structure according to the embodiments of the present application, the first pixel group 110 is arranged close to the center of the repeat unit 100. Optionally, the two second sub-pixels 12 in the second pixel group 120 include two second outer edges that are adjacent to each other and located at a side away from the first sub-pixel 11, and the two second outer edges intersect. The repeat unit 100 includes side edges that are adjacent and intersect, and each of the second outer edges overlaps a portion of one of the side edges. When the repeat units 100 are arranged in an array, the space between the second sub-pixels 12 in adjacent two repeat units 100 can be reduced.

In some other optional embodiments, the two third sub-pixels 13 in the third pixel group 130 include two third outer edges that are adjacent to each other and located at a side away from the first sub-pixel 11, and the two third outer edges intersect. The repeat unit 100 includes side edges that are adjacent and intersect, and each of the third outer edges overlaps a portion of one of the side edges. When the repeat units 100 are arranged in an array, the space between the third sub-pixels 13 in adjacent two repeat units 100 can be reduced.

N may be set in a variety of ways, for example, N may be 6, that is, the repeat unit 100 is a hexagon, or N may be 4, that is, the repeat unit 100 is a quadrilateral.

Still referring to FIG. 1, according to the pixel arrangement structure of the embodiments of the present application, N is 4, the repeat unit 100 is a quadrilateral and includes two second pixel groups 120 and two third pixel groups 130, and the first pixel group 110 includes two first sub-pixels 11. That is, the repeat unit 100 includes four second sub-pixels 12, four third sub-pixels 13 and two first sub-pixels 11.

In these optional embodiments, the repeating unit 100 is a quadrilateral and includes four second sub-pixels 12 and four third sub-pixels 13, so that the outer edge of each of the second sub-pixels 12 and each of the third sub-pixels 13 can overlap a portion of a side edge of the repeat unit 100, an area ratio of the second sub-pixels 12 and the third sub-pixels 13 in the repeat unit 100 is increased. The second sub-pixel 12 and the third sub-pixel 13 that are adjacent can form a pixel display unit 200 with the first sub-pixel 11, and adjacent two pixel display units 200 share one first sub-pixel 11.

When N is 4, as shown in FIGS. 1 and 2, four pixel display units 200 can be formed in the repeat unit 100.

In some other embodiments, still referring to FIG. 2, when N is 4, the repeat unit 100 is a quadrilateral and includes two second pixel groups 120 and two third pixel groups 130, the first pixel group 110 includes four first sub-pixels 11. In this pixel arrangement structure, no sub-pixel is shared for the pixel display units 200.

Optionally, the repeat unit 100 may be a rectangle and includes at least two diagonals, the repeat unit 100 is divided by any one of the diagonals into two portions of a same area, and in the repeat unit 100, four second sub-pixels 12 and/or third sub-pixels 13 are arranged at two sides of any one of the diagonals. Optionally, the angle between the first direction and/or the second direction of the diagonals is 45°. In some embodiments, the repeat unit 100 includes at least two diagonals, in which any one of the diagonals divides the repeat unit 100 into two portions of a same area.

In these optional embodiments, when the repeat units 100 are arranged in an array along a first direction and a second direction, since the four second sub-pixels 12 and/or third sub-pixels 13 are arranged at two sides of any one of the diagonals, the second sub-pixels 12 or the third sub-pixels 13 in adjacent two repeat units 100 can be adjacent by reasonably arranging the repeat units 100, so that a larger mask plate opening can be used for evaporation of four or even eight second sub-pixels 12 and/or third sub-pixels 13.

In addition, the four second sub-pixels 12 and/or third sub-pixels 13 in the repeat unit 100 are arranged at two sides of any one of the diagonals. When the repeat units 100 are distributed in an array along the first direction and the second direction to form the pixel structure, clear and fine monochrome line display can be achieved along the first direction, the second direction and the direction of the diagonals, and the display effect of the pixel arrangement structure can be further improved.

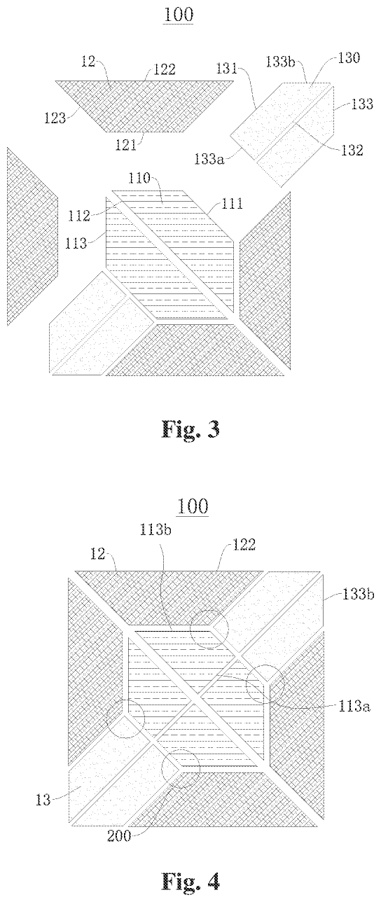

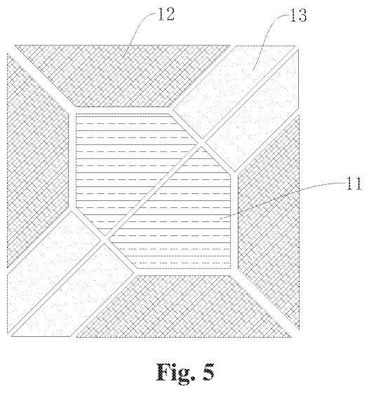

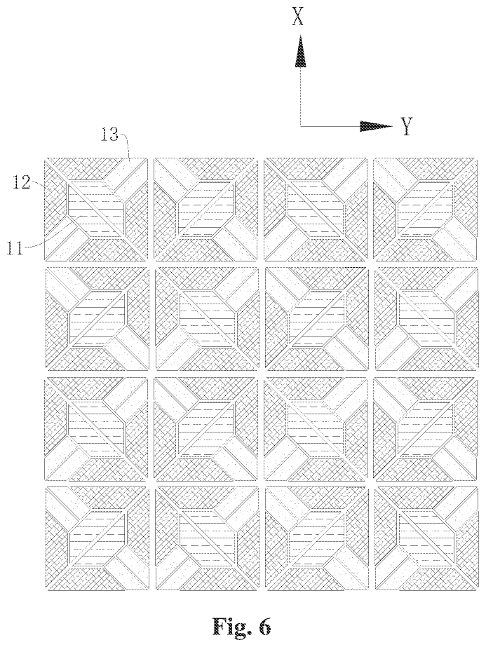

Referring to FIGS. 3-5 together, in which FIG. 3 shows a schematic structural diagram of a repeat unit 100 in a pixel arrangement structure according to yet another embodiment of the first aspect of the present application, FIG. 4 shows a schematic structural diagram of a repeat unit 100 in a pixel arrangement structure according to yet another embodiment of the first aspect of the present application, and FIG. 5 shows a schematic structural diagram of a repeat unit 100 in a pixel arrangement structure according to yet another embodiment of the first aspect of the present application.

According to the pixel arrangement structure of the embodiments of the present application, the repeat unit 100 is a square, and at least one of the first pixel group 110, the second pixel group 120 and the third pixel group 130 is symmetrically arranged about the diagonals. Therefore, the distribution of sub-pixels of different colors in the pixel arrangement structure is more uniform.

The repeat unit 100 is decomposed in FIG. 3 to better illustrate the structures of the various first sub-pixels 11, second sub-pixels 12 and third sub-pixels 13 in the repeat unit 100, and in FIG. 3, the repeat unit 100 can be a square by reasonably adjusting the space among the first sub-pixels 11, the second sub-pixels 12 and the third sub-pixels 13.

For example, in the repeat unit 100, at least four second sub-pixels 12 and/or at least four third sub-pixels 13 are symmetrically arranged about the diagonals, and/or the at least two first sub-pixels 11 in the first pixel group 110 are symmetrically arranged about the diagonal.

In some embodiments, the second sub-pixel 12 is a trapezoid and includes a second upper edge 121 and a second lower edge 122 opposite to each other and a second side edge 123 connecting the second upper edge 121 and the second lower edge 122, in which a length of the second upper edge 121 is less than a length of the second lower edge 122 and the second lower edge 122 is located at a side of the second upper edge 121 away from the first sub-pixel 11, and in the second pixel group 120, adjacent two second side edges 123 of the two second sub-pixels 12 are parallel.

The second sub-pixel 12 is, for example, a quadrilateral, and in a same pixel display unit 200, the second side edge 123 of the second sub-pixel 12 is adjacent to the third sub-pixel 13, and the second side edge 123 is parallel to an outer edge of at least one of the third sub-pixels 13. The distance between the second sub-pixel 12 and the third sub-pixel 13 in a same pixel display unit 200 can be reduced.

The third sub-pixel 13 is, for example, a trapezoid and includes a third upper edge 131 and a third lower edge 132 opposite to each other and a third side edge 133 connecting the third upper edge 131 and the third lower edge 132, and a length of the third upper edge 131 is less than a length of the third lower edge 132.

In a same pixel display unit 200, the third upper edge 131 and the second side edge 123 are adjacent and parallel to each other. In the third pixel group 130, the third lower edges 132 of the two third sub-pixels 13 are adjacent and parallel to each other.

Optionally, the third sub-pixel 13 is a right-angled trapezoid, and the third side edge 133 includes a third right-angled side edge 133a and a third bevel side edge 133b. The first sub-pixel 11 is a polygon, and in a same pixel display unit 200, the third right-angled side edge 133a and an outer edge of the first sub-pixel 11 are adjacent and parallel to each other, and the third bevel side edge 133b overlaps a portion of a side edge of the repeat unit 100. The space between the third sub-pixel 13 and the first sub-pixel 11 can be reduced.

Optionally, in a same pixel display unit 200, the second upper edge 121 of the second sub-pixel 12 and one of the outer edges of the first sub-pixel 11 are adjacent and parallel to each other, and the space between the second sub-pixel 12 and the first sub-pixel 11 can be reduced.

When the ratio of numbers of the first sub-pixels 11, the second sub-pixels 12 and the third sub-pixels 13 in the repeat unit 100 is 1:2:2, the first sub-pixel 11 may, for example, be a trapezoid and include a first upper edge 111, a first lower edge 112 and a first side edge 113 connecting the first upper edge 111 and the first lower edge 112.

In the repeat unit 100, the first side edge 113 and the second upper edge 121 are adjacent and parallel to each other. The first upper edge 111 and the third side edge 133 (e.g., the third right-angled side edge 133a) are adjacent and parallel to each other. In the first pixel group 110, the first lower edges 112 of the two first sub-pixels 11 are adjacent and parallel to each other.

Alternatively, as shown in FIG. 4, when the ratio of the numbers of the first sub-pixels 11, the second sub-pixels 12 and the third sub-pixels 13 in the repeat unit 100 is 1:1:1, the first sub-pixel 11 may, for example, be a right-angled trapezoid, and the first side edge 113 includes a first right-angled side edge 113a and a first bevel side edge 113b. In a same pixel display unit 200, the first upper edge 111 and one of the third side edges 133 (e.g., the third right-angled side edge 133a) are adjacent and parallel to each other. The first bevel side edge 113b and the second upper edge 121 are adjacent and parallel to each other.

Alternatively, as shown in FIG. 5, the first sub-pixel 11 is a polygon, and in a same pixel display unit 200, the first sub-pixel 11 includes an outer edge adjacent to the second upper edge 121 and another outer edge adjacent to the third side edge 133 (e.g., the third right-angled side edge 133a).

Referring to FIG. 6, which shows a schematic structural diagram of a pixel arrangement structure according to an embodiment of the first aspect of the present application.

According to the pixel arrangement structure of the embodiments of the present application, the repeat units 100 are arranged in an array along the first direction (the Y direction in FIG. 6) and the second direction (the X direction in FIG. 6), and two columns of the repeat units 100 that are adjacent along the first direction are symmetrically distributed about an axis extending along the second direction. Therefore, the second sub-pixels 12 or the third sub-pixels 13 of the two columns of the repeat units 100 that are adjacent can be adjacent, and the second sub-pixels 12 of the two columns of the repeat units 100 that are adjacent can be formed by evaporation molding with a shared opening.

Optionally, two rows of the repeat units 100 that are adjacent along the second direction are symmetrically distributed about an axis extending along the first direction. Therefore, the second sub-pixels 12 or the third sub-pixels 13 of the two rows of the repeat units 100 that are adjacent can be adjacent, and the second sub-pixels 12 of the two rows of the repeat units 100 that are adjacent can be formed by evaporation molding with a shared opening.

In some embodiments, two columns of the repeat units 100 that are adjacent along the first direction are symmetrically distributed about an axis extending along the second direction, and two rows of the repeat units 100 that are adjacent along the second direction are symmetrically distributed about an axis extending along the first direction, so that the second sub-pixels 12 or the third sub-pixels 13 in adjacent four repeat units 100 can be adjacent, and the eight second sub-pixels 12 or the eight third sub-pixels 13 can be formed by evaporation molding with a shared opening.

Optionally, the shape and area of the second sub-pixel 12 and the third sub-pixel 13 may be the same or different. For example, in the pixel arrangement structure as shown in FIGS. 3 and 4, the second sub-pixel 12 and the third sub-pixel 13 are of different shapes and areas.

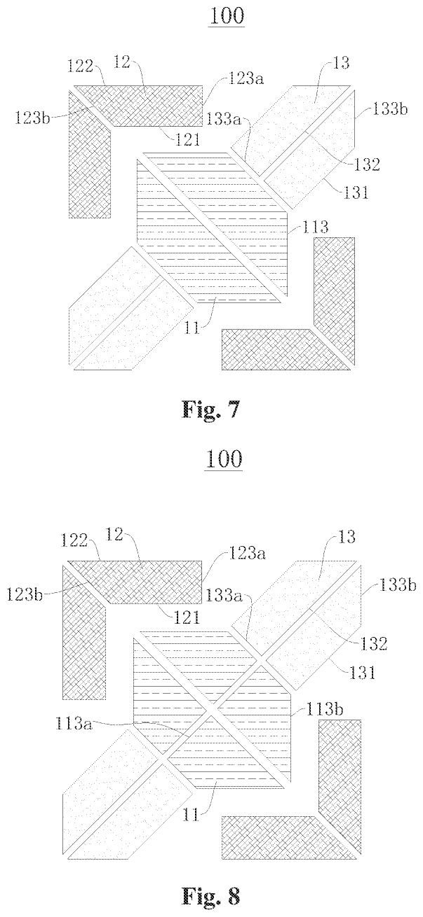

Referring to FIGS. 7 and 8 together, in which FIG. 7 shows a schematic structural diagram of a repeat unit 100 in a pixel arrangement structure according to yet another embodiment of the first aspect of the present application, and FIG. 8 shows a schematic structural diagram of a repeat unit 100 in a pixel arrangement structure according to yet another embodiment of the first aspect of the present application.

In some other embodiments, the second sub-pixel 12 and the third sub-pixel 13 are of the same shape and area. Therefore, the second sub-pixel 12 and the third sub-pixel 13 can be formed by evaporation molding with a same mask plate, and the evaporation process for the pixel arrangement structure is simplified.

Further, in the embodiments as shown in FIGS. 3 and 4, in a same pixel display unit 200, one of the second side edges 123 and the third upper edge 131 are adjacent and parallel to each other. In the embodiments as shown in FIGS. 7 and 8, in a same pixel display unit 200, one of the second side edges 123 and the third upper edge 131 are not parallel to each other.

In the embodiments as shown in FIGS. 7 and 8, the arrangement of the first sub-pixels 11 may be the same as that of the embodiments as shown in FIGS. 3 and 4.

Optionally, the repeat unit 100 as shown in FIG. 7 and/or FIG. 8 may also be arranged in the above arrangement.

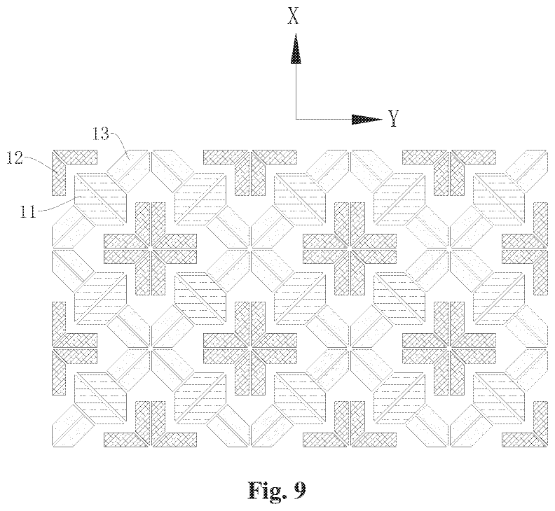

Referring to FIG. 9, which shows a schematic structural diagram of a pixel arrangement structure according to another embodiment of the first aspect of the present application.

When the repeat units 100 as shown in FIG. 7 are arranged in an array along the first direction and the second direction, two columns of the repeat units 100 that are adjacent along the first direction are symmetrically distributed about an axis extending along the second direction, and/or two rows of the repeat units 100 that are adjacent along the second direction are symmetrically distributed about an axis extending along the first direction.

In the pixel arrangement structure as shown in FIG. 9, since the second sub-pixel 12 and the third sub-pixel 13 are of the same shape and area, the second sub-pixel 12 and the third sub-pixel 13 are arranged at an inclined angle of 45°. After the evaporation of the second sub-pixel 12 by the mask plate is finished, the second sub-pixel 12 may be rotated 45° or 135° to continue the evaporation the third sub-pixel 13.

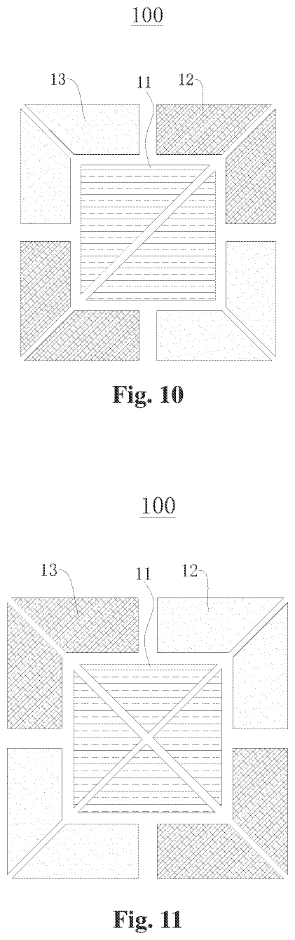

Referring to FIGS. 10 and 11 together, in which the arrangement of the third pixel groups 130 and the first sub-pixels 11 in the repeat unit 100 is different from that in FIGS. 7 and 8.

According to the pixel arrangement structure of the embodiments of the present application, the third sub-pixel 13 is a right-angled trapezoid, and in a same pixel display unit 200, the third right-angled side edge 133a and the second right-angled side edge 123a are adjacent and parallel to each other. In a same third pixel group 130, the third lower edges 132 of the two third sub-pixels 13 are adjacent and parallel to each other.

Optionally, in a same pixel display unit 200, the third upper edge 131 and one of the outer edges of the first sub-pixel 11 are adjacent and parallel to each other. The third lower edge 132 is located at a side of the third upper edge 131 away from the first sub-pixel 11 and overlaps a portion of a side edge of the repeat unit 100.

The first sub-pixel 11 is a right triangle, and as shown in FIG. 10, when the ratio of numbers of the first sub-pixels 11, the second sub-pixels 12 and the third sub-pixels 13 in the repeat unit 100 is 1:2:2, the right-angled edge of the first sub-pixel 11 is adjacent to the second upper edge 121 and the third upper edge 131, and the bottom edge of the first sub-pixel 11 is parallel to the diagonal.

Alternatively, as shown in FIG. 11, when the ratio of numbers of the first sub-pixels 11, the second sub-pixels 12 and the third sub-pixels 13 in the repeat unit 100 is 1:1:1, the two right-angled edges of the first sub-pixel 11 are parallel to the two diagonals, respectively, and the bottom edge of the first sub-pixel 11 is adjacent to the second upper edge 121 and the third upper edge 131.

The repeat unit 100 as shown in FIGS. 10 and 11 may also be arranged in the above arrangement.

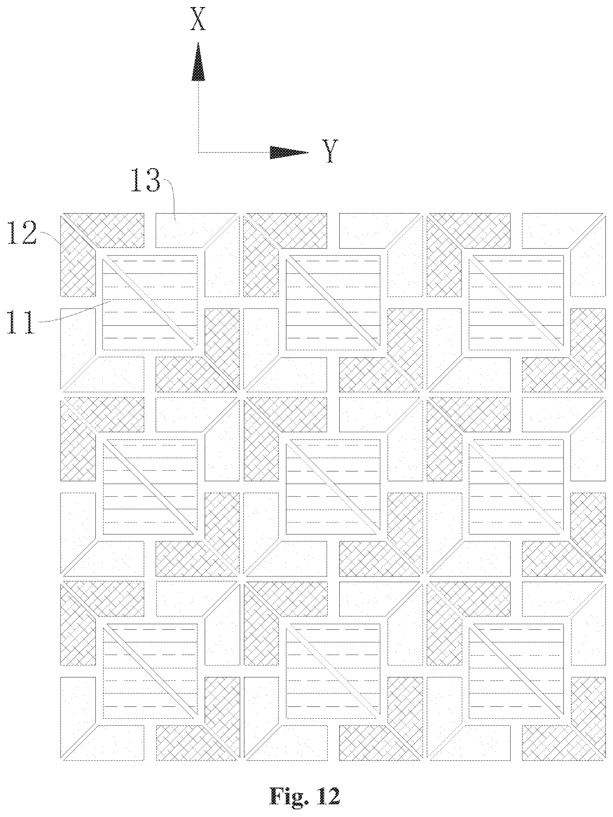

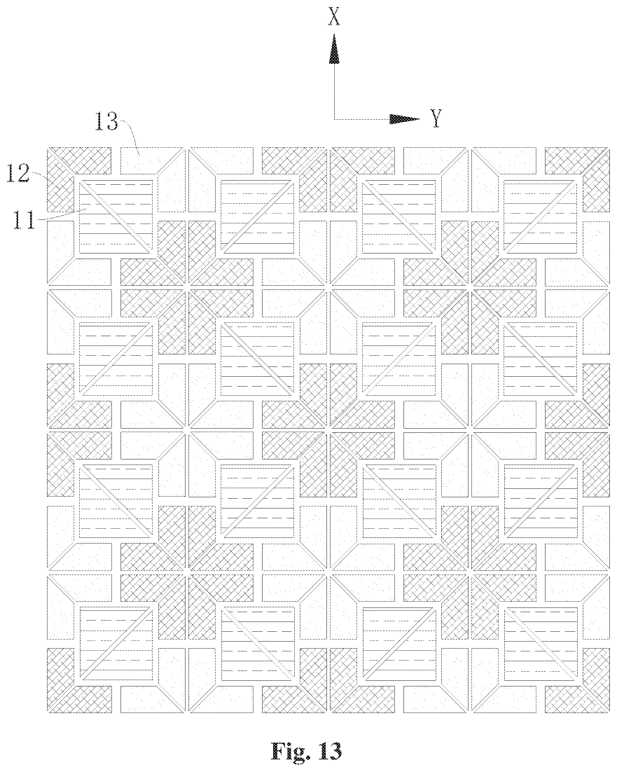

Referring to FIGS. 12 and 13 together, when the repeat units 100 as shown in FIG. 10 are arranged in an array along the first direction and the second direction, two columns of the repeat units 100 that are adjacent along the first direction are symmetrically distributed about an axis extending along the second direction, and/or two rows of the repeat units 100 that are adjacent along the second direction are symmetrically distributed about an axis extending along the first direction.

In the pixel arrangement structure as shown in FIGS. 12 and 13, the second sub-pixel 12 is arranged in the same way as the third sub-pixel 13, and since the second sub-pixel 12 and the third sub-pixel 13 are of the same shape and area, the second sub-pixel 12 and the third sub-pixel 13 can be formed by evaporation molding with a same mask plate.

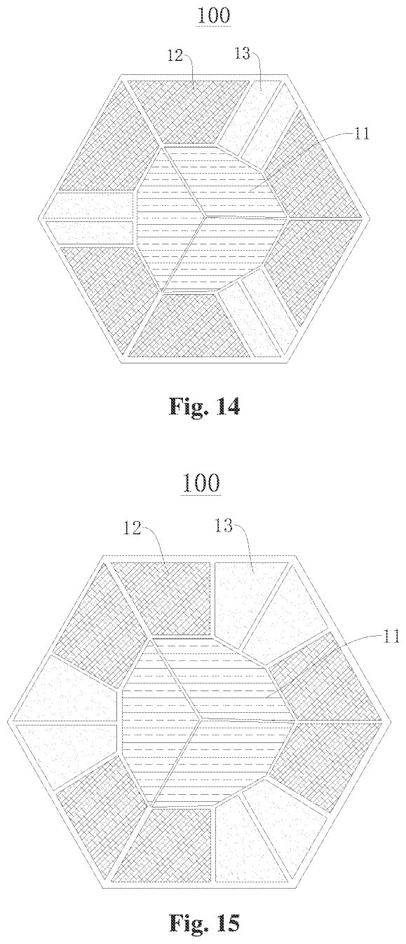

In some other embodiments, N may be 6. Referring to FIG. 14, which shows a schematic structural diagram of a repeat unit 100 in a pixel arrangement structure according to yet another embodiment of the first aspect of the present application.

As shown in FIG. 14, in the pixel arrangement structure of the embodiments of the present application, N is 6, and the repeat unit 100 is a hexagon. The repeat unit 100 includes a first pixel group 110 and three second pixel groups 120 and three third pixel groups 130 surrounding the first pixel group 110, the first pixel group 110 includes three first sub-pixels 11, and the three second pixel groups 120 and the three third pixel groups 130 are alternately arranged on a peripheral side of the first pixel group 110 to form second sub-pixel 12 and third sub-pixel 13 that are adjacent, which form a pixel display unit 200 with the first sub-pixel 11 at the center.

The ratio of numbers of the first sub-pixels 11, the second sub-pixels 12 and the third sub-pixels 13 in the repeat unit 100 is 1:2:2, the second sub-pixel 12 and third sub-pixel 13 that are adjacent form a pixel display unit 200 with the first sub-pixel 11 at the center, and adjacent pixel display units 200 share one first sub-pixel 11. Six pixel display units 200 are formed in the repeat unit 100.

Referring to FIG. 15, which shows a schematic structural diagram of a repeat unit 100 in a pixel arrangement structure according to yet another embodiment of the first aspect of the present application.

In some other embodiments, when the ratio of numbers of the first sub-pixels 11, the second sub-pixels 12 and the third sub-pixels 13 in the repeat unit 100 is 1:1:1, the first pixel group 110 includes six first sub-pixels 11, each adjacent pair of second sub-pixel 12 and third sub-pixel 13 is corresponding to a first sub-pixel 11, and the first sub-pixel 11, the second sub-pixel 12 and the third sub-pixel 13 that are adjacent form a pixel display unit 200, in which all the sub-pixels that are not shared are true sub-pixels.

Optionally, the arrangement of the second sub-pixels 12 and the third sub-pixels 13 may the same as that in FIGS. 3 and 4.

The first sub-pixel 11 is a polygon, and in a same pixel display unit 200, an outer edge of the first sub-pixel 11 is adjacent to the second upper edge 121, another outer edge of the first sub-pixel 11 is adjacent to the third upper edge 131.

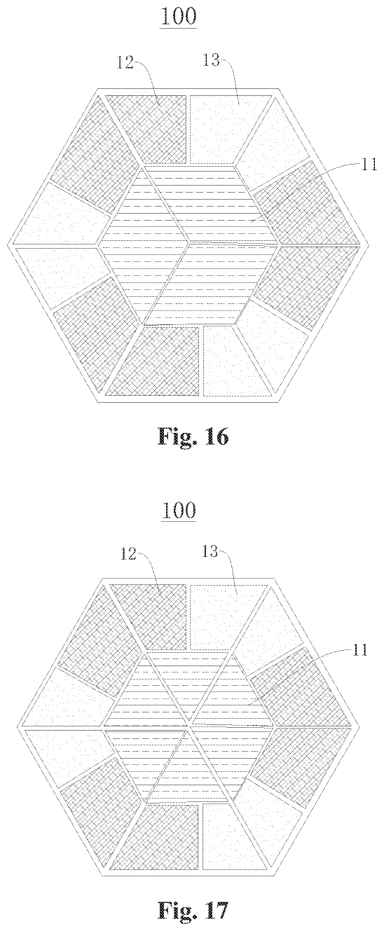

Referring to FIG. 16, which shows a schematic structural diagram of a repeat unit 100 in a pixel arrangement structure according to yet another embodiment of the first aspect of the present application.

In some other embodiments, when N is 6, the second sub-pixels 12 and the third sub-pixel 13s may also be arranged in the same manner as in FIGS. 10 and 11. Each of the second sub-pixels 12 and the third sub-pixels 13 is a right-angled trapezoid, and in a same pixel display unit 200, the second right-angled side edge 123a and the third right-angled side edge 133a are adjacent and parallel to each other, and the third upper edge 131 and the second upper edge 121 are adjacent to a same outer edge of the first sub-pixel 11. In a same second pixel group 120, two second bevel side edges 123b are adjacent and parallel to each other.

When the ratio of numbers of the first sub-pixels 11, the second sub-pixels 12 and the third sub-pixels 13 in the repeat unit 100 is 1:2:2, the first sub-pixel 11 is a parallelogram. Optionally, the first sub-pixel 11 is a diamond.

Alternatively, referring to FIG. 17, when the ratio of numbers of the first sub-pixels 11, the second sub-pixels 12 and the third sub-pixels 13 in the repeat unit 100 is 1:1:1, the first sub-pixel 11 is a triangle, and optionally, the first sub-pixel 11 is an equilateral triangle.

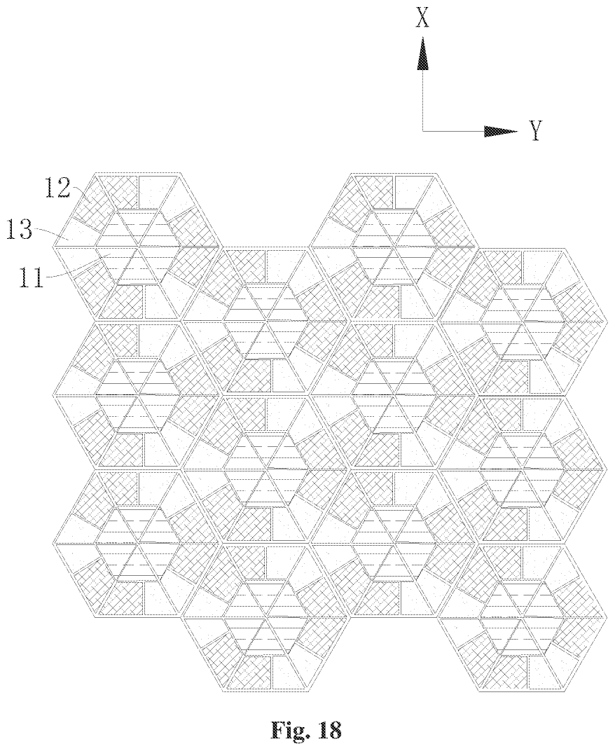

Referring to FIG. 18, which shows a schematic structural diagram of a pixel arrangement structure according to yet another embodiment of the first aspect of the present application.

When the repeat units 100 are arranged in an array along the first direction and the second direction, in adjacent three repeat units 100, three second pixel groups 120 or three third pixel groups 130 are adjacent, so that six second sub-pixels 12 are adjacent and can be formed by evaporation molding with a shared opening of a mask plate, and six third sub-pixels 13 are adjacent and can be formed by evaporation molding with a shared opening of a mask plate.

Optionally, when the second sub-pixel 12 and the third sub-pixel 13 are of the same shape and area, the second sub-pixel 12 and the third sub-pixel 13 are arranged in a same pattern and can be formed by evaporation molding with a same mask plate.

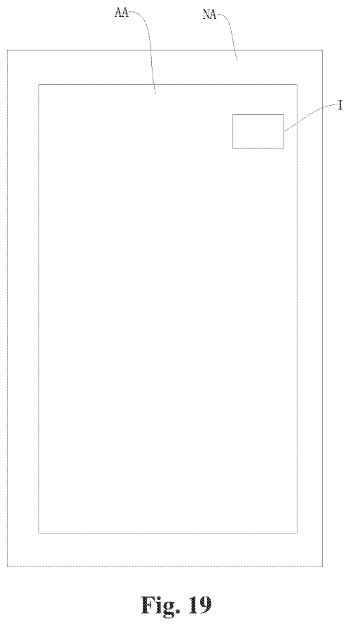

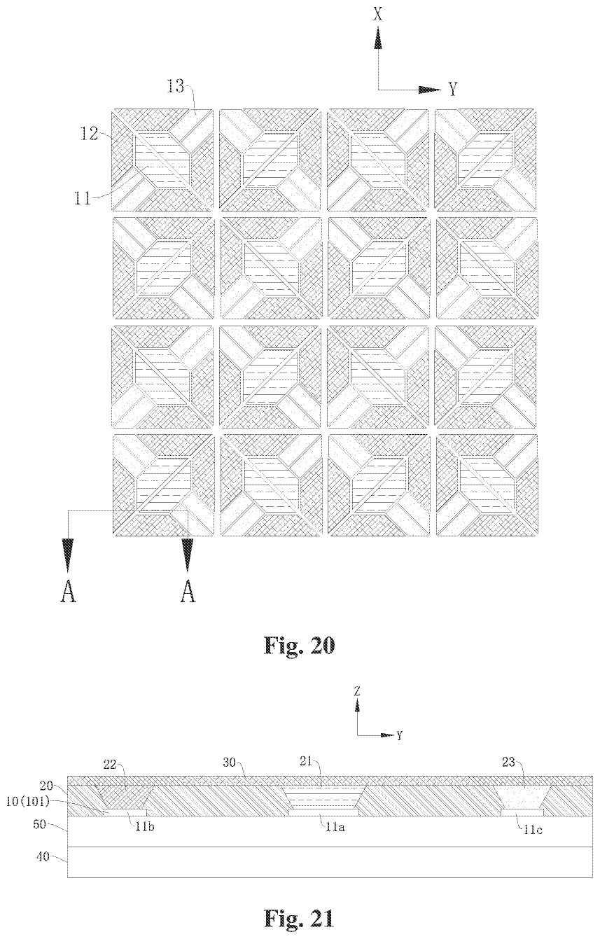

Referring to FIGS. 19 and 20 together, in which FIG. 19 shows a schematic structural diagram of a display panel according to an embodiment of the present application, and FIG. 20 shows a partially enlarged schematic structural diagram of area I in FIG. 19. Embodiments of the second aspect of the present application further provide a display panel including the pixel arrangement structure of any one of the above embodiments. Since the display panel according to the embodiments of the present application includes the pixel arrangement structure of any one of the above embodiments, the display panel has the beneficial effects of the pixel arrangement structure, which will not be repeated herein.

In some optional embodiments, the display panel includes a display area AA and a non-display area NA surrounding the display area AA. In other embodiments, the display panel may include only the display area AA without the non-display area NA. A partial magnification of the display area AA shows that the display panel utilizes the pixel arrangement structure as described above.

Referring to FIG. 21, which shows a cross-sectional view at A-A in FIG. 20.

In some optional embodiments, the display panel further includes a first electrode layer 10, a light-emitting structure layer 20 and a second electrode layer 30, and the light-emitting structure layer 20 includes a first light-emitting structure 21, a second light-emitting structure 22 and a third light-emitting structure 23, which are arranged in the same way as the first sub-pixel 11, the second sub-pixel 12 and the third sub-pixel 13 in the pixel arrangement structure.

One of the first electrode layer 10 and the second electrode layer 30 is the anode and the other is the cathode. In the embodiments of the present application, for example, the first electrode layer 10 is the anode. When the first electrode layer 10 is the anode, the first electrode layer 10 includes a plurality of first anode block 11a, second anode block 11b and third anode block 11c, the first light-emitting structure 21 is arranged accordingly to the first anode block 11a in one-to-one correspondence, the second light-emitting structure 22 is arranged accordingly to the second anode block 11b in one-to-one correspondence, and the third light-emitting structure 23 is arranged accordingly to the third anode block 11c in one-to-one correspondence. When the second electrode layer 30 is the cathode, the second electrode layer 30 may be a common electrode formed as a whole.

In some optional embodiments, the second sub-pixel 12 is arranged accordingly to the second anode block 11b, and the second sub-pixel 12 and the second anode block 11b are in one-to-one correspondence, so that the second sub-pixels 12 can be controlled independently of each other.

Optionally, the first sub-pixel 11 is arranged accordingly to the first anode block 11a, and the first sub-pixel 11 and the first anode block 11a are in one-to-one correspondence, so that the first sub-pixels 11 can be controlled independently of each other.

Optionally, the third sub-pixel 13 is arranged accordingly to the third anode block 11c, and the third sub-pixel 13 and the third anode block 11c are in one-to-one correspondence, so that the third sub-pixels 13 can be controlled independently of each other.

In some optional embodiments, the display panel further includes a substrate 40 and a device layer 50 located on the substrate 40, when the first electrode layer 10 is an anode layer, the first electrode layer 10 is located on the device layer 50, the light-emitting structure layer 20 is located on the first electrode layer 10, and the second electrode layer 30 is located on the light-emitting structure layer 20.

The substrate 40 may be made of a light-transmitting material such as glass, Polyimide (PI). The device layer 50 may include pixel circuits for driving the various sub-pixels to display.

Embodiments of the third aspect of the present application further provide an electronic device including the display panel as described above. Since the electronic device includes the display panel, the electronic device has all the beneficial effects of the display panel, which will not be repeated herein.

Herein, the type of the electronic device is not limited, for example, the electronic device may be a mobile terminal, a display, etc.

Embodiments of the fourth aspect of the present application further provide a mask assembly to be applied for evaporation of the pixel arrangement structure according to any one of the embodiments of the first aspect of the present application. The mask assembly includes: a first mask plate configured for evaporation of the first sub-pixels 11 and including a first evaporation opening adapted to an outer contour of a plurality of the first sub-pixels 11 that are adjacent in the pixel arrangement structure; a second mask plate configured for evaporation of the second sub-pixels 12 and including a second evaporation opening adapted to an outer contour of a plurality of the second sub-pixels 12 that are adjacent in the pixel arrangement structure; and a third mask plate configured for evaporation of the third sub-pixels 13 and including a third vaporization opening adapted to an outer contour of a plurality of the third sub-pixels 13 that are adjacent in the pixel arrangement structure.

Those skilled in the art should understand that all the above embodiments are exemplary ant not limiting. Different technical features in different embodiments can be combined to achieve beneficial effects. Those skilled in the art can understand and implement other variations of the embodiments described above based on the accompanying drawings, specification, and claims. Any reference numeral in the claims should not be construed as limiting the scope of claims. The function of multiple parts in the claims can be implemented by a single hardware or software module. The presence of certain technical features in different dependent claims does not mean that these technical features cannot be combined to achieve beneficial effects.

What is claimed is:

1. A pixel arrangement structure comprising a plurality of repeat units arranged in an array, each of the repeat units being an N polygon, N≥4 and N being an even number, wherein the repeat unit comprises:
a first pixel group comprising at least two first sub-pixels;
at least two second pixel groups, each of the second pixel groups comprising two second sub-pixels; and
at least two third pixel groups, each of the third pixel groups comprising two third sub-pixels, the at least two second pixel groups and the at least two third pixel groups being alternately arranged on a peripheral side of the first pixel group.

2. The pixel arrangement structure of claim 1, wherein
in the repeat unit, a ratio of numbers of the first sub-pixels, the second sub-pixels and the third sub-pixels is 1:2:2, the first sub-pixel, the second sub-pixel and the third sub-pixel form a pixel display unit, and the first sub-pixel is shared by adjacent two pixel display units; or
in the repeat unit, the first pixel group comprises two first sub-pixels, and a ratio of the numbers of the first sub-pixels, the second sub-pixels and the third sub-pixels is 1:1:1.

3. The pixel arrangement structure of claim 1, wherein
N is 6, the repeat unit is a hexagon and comprises the first pixel group, three second pixel groups and three third pixel groups, and the first pixel group comprises three or six first sub-pixels; or
N is 4, the repeat unit is a quadrilateral and comprises the first pixel group, two second pixel groups and two third pixel groups, and the first pixel group comprises two or four first sub-pixels.

4. The pixel arrangement structure of claim 3, wherein the repeat unit comprises at least two diagonals, any one of the diagonals divides the repeat unit into two portions of a same area, and in the repeat unit, at least four second sub-pixels and/or at least four third sub-pixels are arranged at two sides of any one of the diagonals.

5. The pixel arrangement structure of claim 4, wherein the repeat unit is a regular polygon, and at least one of the first pixel group, the second pixel group and the third pixel group is symmetrically arranged about the diagonal.

6. The pixel arrangement structure of claim 5, wherein in the repeat unit, at least four second sub-pixels and at least four third sub-pixels are symmetrically arranged about the diagonals.

7. The pixel arrangement structure of claim 4, wherein the at least two first sub-pixels in the first pixel group are symmetrically arranged about the diagonal.

8. The pixel arrangement structure of claim 4, wherein the second sub-pixels and the third sub-pixels have the same shape and area.

9. The pixel arrangement structure of claim 5, wherein
the second sub-pixel is a trapezoid and comprises a second upper edge and a second lower edge opposite to each other and a second side edge connecting the second upper edge and the second lower edge, wherein a length of the second upper edge is less than a length of the second lower edge and the second lower edge is located at a side of the second upper edge away from the first sub-pixel, and in the second pixel group, adjacent two second side edges of the two second sub-pixels are parallel.

10. The pixel arrangement structure of claim 9, wherein
the second sub-pixel is a quadrilateral and adjacent to the third sub-pixel by the second side edge, and the second side edge is parallel to an outer edge of at least one of the third sub-pixels.

11. The pixel arrangement structure of claim 10, wherein the second sub-pixel is a right-angled trapezoid, the second side edge comprises a second right-angled side edge, the second sub-pixel is adjacent to the third sub-pixel by the second right-angled side edge, and the second right-angled side edge is parallel to the outer edge of at least one of the third sub-pixels.

12. The pixel arrangement structure of claim 10, wherein the third sub-pixel is a trapezoid and comprises a third upper edge and a third lower edge opposite to each other and a third side edge connecting the third upper edge and the third lower edge, and a length of the third upper edge is less than a length of the third lower edge.

13. The pixel arrangement structure of claim 12, wherein the third lower edge is located at a side of the third upper edge away from the first sub-pixel, in the third pixel group, adjacent two third side edges of the two third sub-pixels are parallel, and for the second sub-pixel and the third sub-pixel that are adjacent, the second side edge and the third side edge are adjacent and parallel.

14. The pixel arrangement structure of claim 12, wherein the third sub-pixel is a right-angled trapezoid, the second side edge comprises a second right-angled side edge, the third side edge comprises a third right-angled side edge, and in the repeat unit, the second right-angled side edge and the third right-angled side edge that are adjacent are parallel.

15. The pixel arrangement structure of claim 12, wherein the first sub-pixel is a polygonal, and the second upper edge and the third upper edge of the second sub-pixel and the third sub-pixel that are adjacent are arranged adjacent to a same outer edge of the first sub-pixel.

16. The pixel arrangement structure of claim 1, wherein the repeat units are arranged in the array along a first direction and a second direction; and
two columns of the repeat units that are adjacent along the first direction are symmetrically distributed about an axis extending along the second direction.

17. The pixel arrangement structure of claim 16, wherein two rows of the repeat units that are adjacent along the second direction are symmetrically distributed about an axis extending along the first direction.

18. A display panel comprising the pixel arrangement structure of claim 1.

19. A mask assembly to be applied for evaporation of the pixel arrangement structure of claim 1, the mask assembly comprising:
a first mask plate configured for evaporation of the first sub-pixels and comprising a first evaporation opening adapted to an outer contour of a plurality of the first sub-pixels that are adjacent in the pixel arrangement structure;
a second mask plate configured for evaporation of the second sub-pixels and comprising a second evaporation opening adapted to an outer contour of a plurality of the second sub-pixels that are adjacent in the pixel arrangement structure; and
a third mask plate configured for evaporation of the third sub-pixels and comprising a third vaporization opening adapted to an outer contour of a plurality of the third sub-pixels that are adjacent in the pixel arrangement structure.
